(19) United States
(12) Patent Application Publication
(10) Pub. No.: US 2010/0246110 A1
(43) Pub. Date: Sep. 30, 2010

(54) INFORMATION TERMINAL DEVICE

(75) Inventors: Hiroshi Kubo, Kawasaki (JP); Manabu Matsushima, Kawasaki (JP); Yoshifumi Kajiwara, Kawasaki (JP); Kenta Sugimori, Kawasaki (JP); Haruyoshi Yada, Kawasaki (JP); Masayuki Sato, Kawasaki (JP); Katsumi Takada, Kawasaki (JP); Toshifumi Tanida, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 12/732,456

(22) Filed: Mar. 26, 2010

(30) Foreign Application Priority Data
Mar. 30, 2009 (JP) 2009-83760

(51) Int. Cl. H05K 5/00

(52) U.S. Cl. 361/679.01

(57) ABSTRACT

An information terminal device includes a first housing and a second housing slidably connected to each other with a connecting mechanism and that is changeable in state between a closed state in which the two housings overlap each other and an open state in which the two housings overlap each other by an area smaller than in the closed state. The information terminal device includes an elastic sheet component attached to a surface of the second housing that faces the first housing and having a protrusion protruding towards the first housing, and a biasing component that biases the protrusion towards the first housing so as to cause the biased protrusion to be elastically in contact with the first housing when the information terminal device is in the closed state.

### CROSS-REFERENCE TO RELATED APPLICATIONS

This application is based upon and claims the benefit of priority of the prior Japanese Patent Application No. 2009-083760, filed on Mar. 30, 2009, the entire contents of which are incorporated herein by reference.

### FIELD

The present invention relates to information terminal device. The present invention relates to, for example, an information terminal device in which looseness between two housings, which are slidably connected to each other, in the thickness direction thereof when the device is in a closed state can be effectively reduced.

### BACKGROUND

Known examples of information terminal devices, such as cellular phones, in recent years include an information terminal device whose housing is divided into two housings, one of which being movably connected to the other. For example, in a sliding-type cellular phone, a stationary housing having a control section and a movable housing having a display section are slidably connected to each other with a connecting mechanism. An information terminal device of this type can be changed in state between a closed state in which the two housings overlap each other and an open state in which the two housings overlap each other by an area smaller than that in the closed state.

Generally, an information terminal device of this type has a problem in that, when in the closed state, there is looseness between the two housings in the thickness direction thereof. Specifically, although the two housings are partly connected to each other by the connecting mechanism when the information terminal device is in the closed state, a part of the two housings not connected by the connecting mechanism has a gap therebetween, which is equivalent to the thickness of the connecting mechanism. Therefore, when a certain external force is applied to the information terminal device, the information terminal device sometimes becomes loose in a direction in which the two housings move toward or away from each other, that is, the thickness direction of the two housings.

A conceivable method for reducing such looseness in the thickness direction of the two housings involves integrally forming a protrusion with a predetermined height on a surface of the movable housing that faces the stationary housing and bringing the protrusion into contact with the stationary housing when the information terminal device in the closed state so as to absorb the gap equivalent to the thickness of the connecting mechanism.

[Patent Document 1] Japanese Laid-Open patent Publication No. 2008-103989

However, with the aforementioned method of the related art, the looseness between the two housings may not be sufficiently reduced if there is a dimensional variation in the connecting mechanism that connects the two housings.

Specifically, there is often a dimensional variation in the connecting mechanism due to machining limitations, and if such a dimensional variation is excessive, the gap equivalent to the thickness of the connecting mechanism between the two housings may excessively become larger. Since the protrusion integrally formed on the surface of the movable housing that faces the stationary housing has a fixed height, the protrusion becomes incapable of coming into contact with the stationary housing if the distance between the two housings excessively increases. As a result, the protrusion becomes incapable of absorbing the gap equivalent to the thickness of the connecting mechanism, possibly resulting in looseness in the thickness direction of the two housings.

### SUMMARY

According to an aspect of the invention, an information terminal device includes a first housing and a second housing slidably connected to each other with a connecting mechanism and that is changeable in state between a closed state in which the two housings overlap each other and an open state in which the two housings overlap each other by an area smaller than in the closed state. The information terminal device includes an elastic sheet component attached to a surface of the second housing that faces the first housing and having a protrusion protruding towards the first housing, and a biasing component that biases the protrusion towards the first housing so as to cause the biased protrusion to be elastically in contact with the first housing when the information terminal device is in the closed state.

The object and advantages of the invention will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF THE DRAWINGS

FIG. 1 is an external perspective view illustrating the configuration of a cellular phone according to an embodiment.

FIG. 2 is another external perspective view illustrating the configuration of the cellular phone according to the embodiment.

FIG. 3 is an exploded perspective view of the cellular phone in a closed state, as viewed from a movable-housing side.

FIG. 4 is another exploded perspective view of the cellular phone in the closed state, as viewed from a stationary-housing side.

FIG. 5 is a vertical sectional view illustrating a front-end region of the movable housing when the cellular phone according to the embodiment is in the closed state.

FIG. 6 is a horizontal sectional view illustrating the front-end region of the movable housing when the cellular phone according to the embodiment is in the closed state.

### DESCRIPTION OF EMBODIMENTS

An embodiment of an information terminal device disclosed by this application will be described in detail below with reference to the drawings. Although the embodiment to be described below is directed to an example in which the information terminal device disclosed by this application is applied to a sliding-type cellular phone, the information terminal device is widely applicable to information terminal devices with various communicable shapes, such as a rotating-type cellular phone.

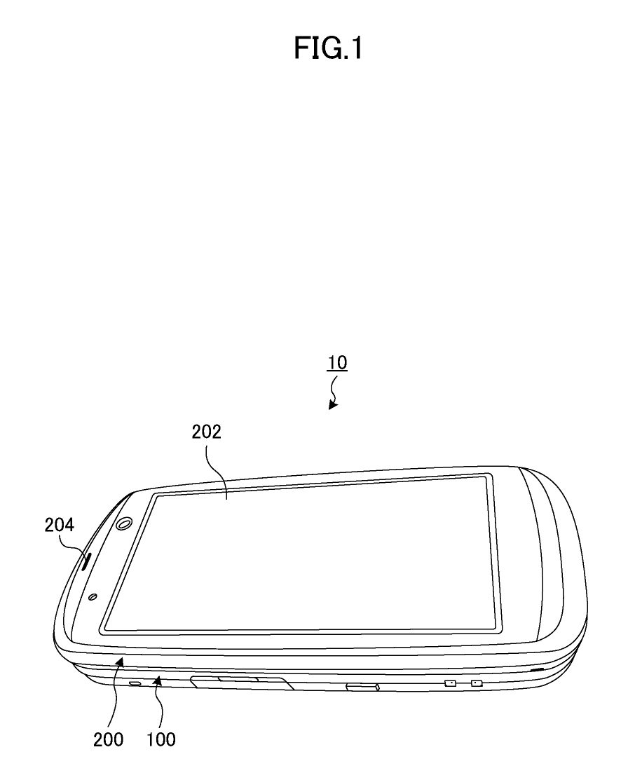

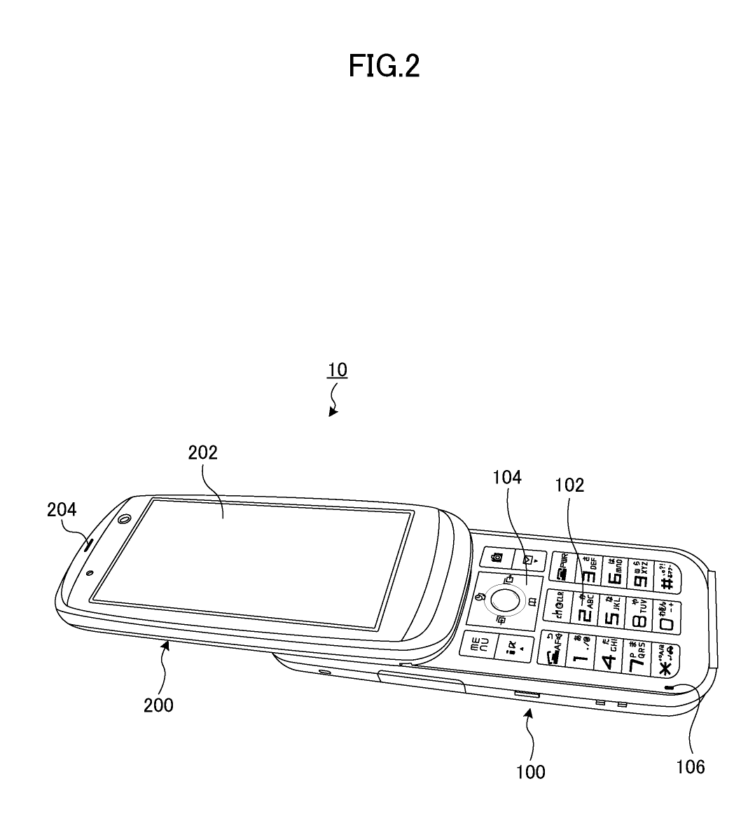

The configuration of a cellular phone 10 according to this embodiment will be described. FIG. 1 is an external perspective view illustrating the configuration of the cellular phone 10 according to an embodiment. FIG. 2 is another external perspective view illustrating the configuration of the cellular phone 10 according to the embodiment.

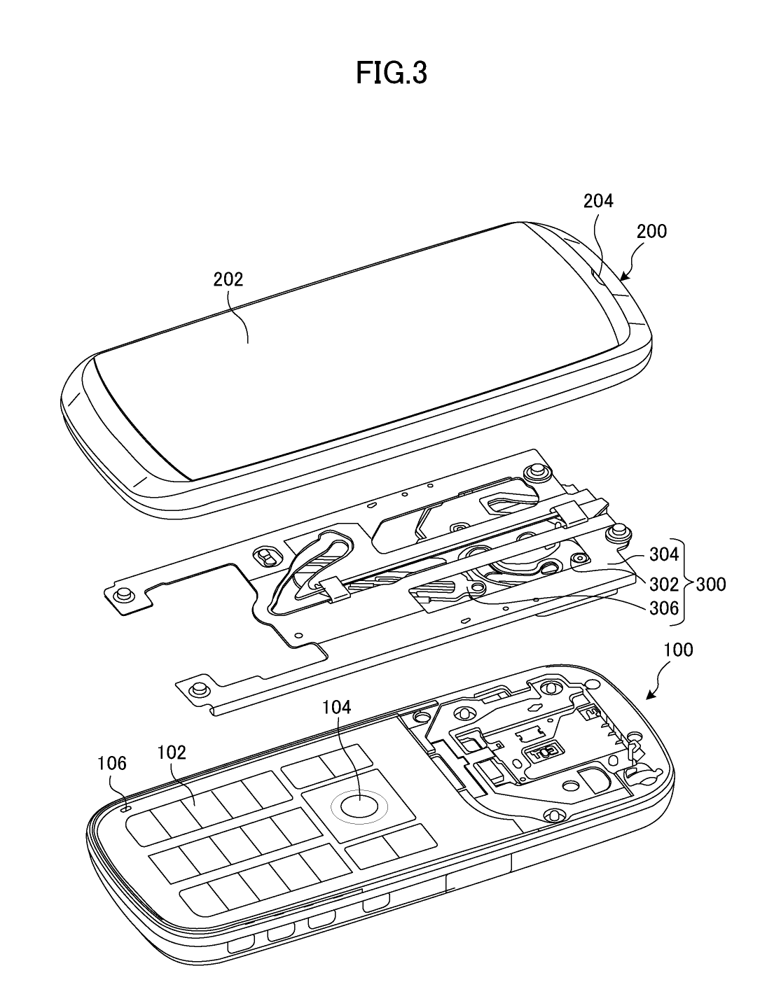

As illustrated in FIGS. 1 and 2, the cellular phone 10 includes a stationary housing 100 serving as a first housing and a movable housing 200 serving as a second housing that are slidably connected to each other with a connecting mechanism 300 (see FIG. 3). The cellular phone 10 may be changed in state between a closed state illustrated in FIG. 1 and an open state illustrated in FIG. 2 by sliding the movable housing 200 relative to the stationary housing 100 in the longitudinal direction.

The closed state illustrated in FIG. 1 is a state in which the stationary housing 100 and the movable housing 200 overlap each other. In this closed state, the overall length of the cellular phone 10 in the longitudinal direction is at minimum. Therefore, when carrying the cellular phone 10 or browsing simple information, such as communication history or information on the Internet, the cellular phone 10 may be set in this closed state.

The open state illustrated in FIG. 2 is a state in which the stationary housing 100 and the movable housing 200 overlap each other by an area smaller than that in the closed state. In the open state, the overall length of the cellular phone 10 in the longitudinal direction is longer than that in the closed state. In the open state, first control buttons 102 and second control buttons 104 serving as a control section of the stationary housing 100 are in an exposed state. Therefore, when making a telephone call or performing an operation such as drafting an outgoing mail using the control buttons 102 and 104, the cellular phone 10 may be set in this open state.

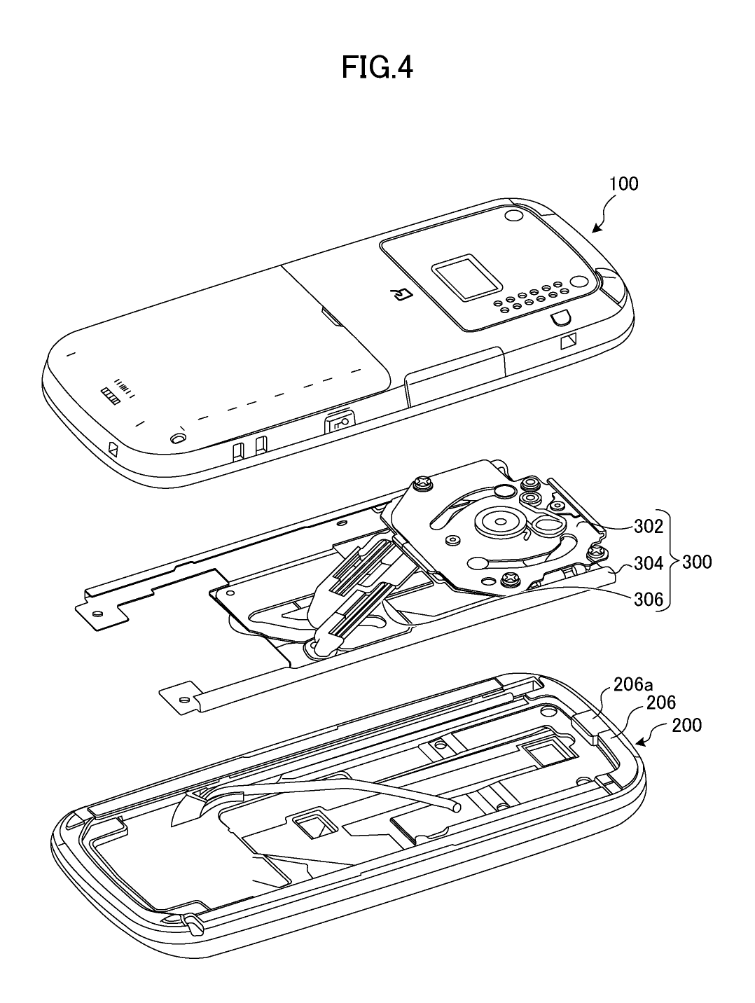

A detailed configuration of the cellular phone 10 will be described. FIG. 3 is an exploded perspective view of the cellular phone 10 in a closed state, as viewed from a movable-housing 200 side. FIG. 4 is another exploded perspective view of the cellular phone 10 in the closed state, as viewed from a stationary-housing 100 side.

For the sake of convenience, when the cellular phone 10 is in the closed state, a direction from the stationary housing 100 towards the movable housing 200 will be referred to as “upward direction” and a direction from the movable housing 200 towards the stationary housing 100 will be referred to as “downward direction”. A direction in which the movable housing 200 is slid relative to the stationary housing 100 when the cellular phone 10 is changed from the closed state to the open state will be referred to as “forward direction”. A direction in which the movable housing 200 is slid relative to the stationary housing 100 when the cellular phone 10 is changed from the open state to the closed state will be referred to as “rearward direction”.

As illustrated in FIGS. 1 to 4, the cellular phone 10 includes the stationary housing 100 provided with the first control buttons 102 and the second control buttons 104 serving as a control section, and also includes the movable housing 200 provided with a display screen 202 serving as a display section.

The stationary housing 100 has a substantially flat rectangular-parallelepiped shape. The upper surface of the stationary housing 100 is provided with, for example, the first control buttons 102, the second control buttons 104, and a transmitter 106. The first control buttons 102 include, for example, a numerical keypad, a talk key, and a talk-end key. The second control buttons 104 include, for example, a direction key and a shortcut key. The transmitter 106 includes a microphone provided inside the stationary housing 100.

Like the stationary housing 100, the movable housing 200 also has a substantially flat rectangular-parallelepiped shape. The upper surface of the movable housing 200 is provided with, for example, the display screen 202 and a receiver 204. The display screen 202 is provided in substantially the middle of the upper surface of the movable housing 200 and is formed of, for example, a liquid-crystal panel or an organic EL display. The display screen 202 may have a touch-screen function so as to allow for operation on the display screen 202 even in the closed state illustrated in FIG. 1.

Referring to FIGS. 3 and 4, the connecting mechanism 300 is interposed between the stationary housing 100 and the movable housing 200. As illustrated in FIGS. 3 and 4, the connecting mechanism 300 includes a base plate 302, a sliding plate 304, and a spring mechanism 306.

The base plate 302 is a substantially square-shaped plate-like component and is fixed to a front-end region on the upper surface of the stationary housing 100 with, for example, screws. The base plate 302 illustrated in FIGS. 3 and 4 also includes a swinging plate rotatably engaged with the base plate 302.

The sliding plate 304 is a substantially rectangular plate-like component and is fixed to the lower surface of the movable housing 200 with, for example, screws. Opposite side edges of the sliding plate 304 are respectively slidably engaged with opposite side edges of the base plate 302.

The spring mechanism 306 is interposed between the base plate 302 and the sliding plate 304 and biases the movable housing 200 in the forward and rearward directions via the base plate 302 and the sliding plate 304. Thus, the movable housing 200 is slidable relative to the stationary housing 100, whereby the cellular phone 10 may be changed between the closed state illustrated in FIG. 1 and the open state illustrated in FIG. 2.

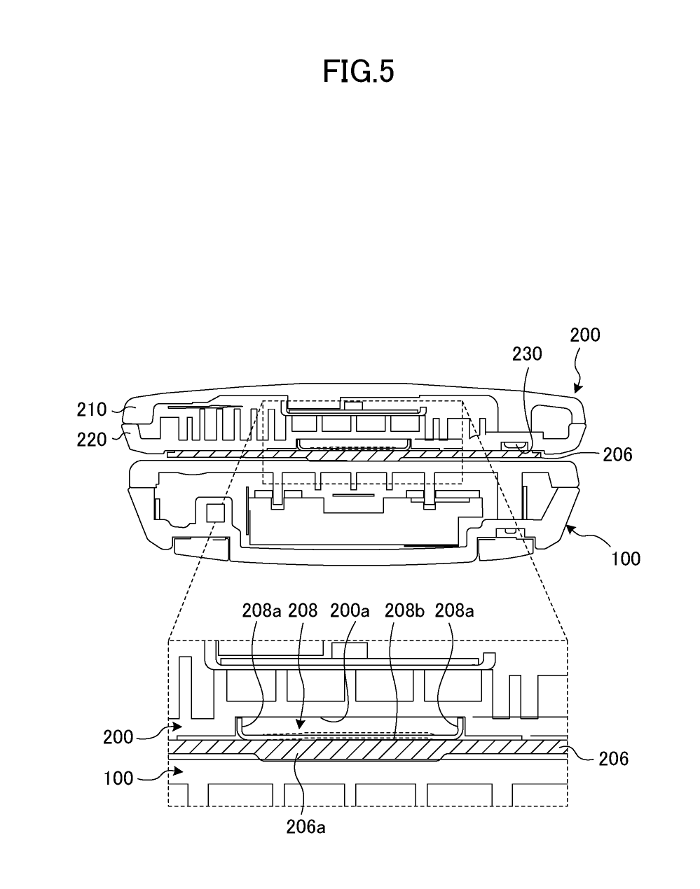

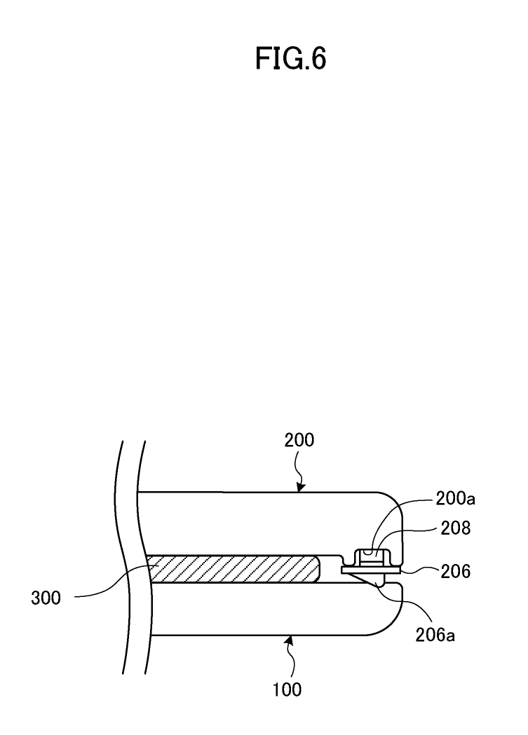

The cellular phone 10 according to this embodiment includes an elastic sheet component 206 attached to a surface of the movable housing 200 that faces the stationary housing 100 and having a protrusion 206a protruding towards the stationary housing 100. The cellular phone 10 according to this embodiment also includes a spring component 208 (see FIGS. 5 and 6) serving as a biasing component that biases the protrusion 206a towards the stationary housing 100 so as to cause the biased protrusion 206a to be elastically in contact with the stationary housing 100 when the cellular phone 10 is in the closed state.

According to the above configuration, looseness between the stationary housing 100 and the movable housing 200 in the thickness direction thereof when the cellular phone 10 is in the closed state may be effectively reduced. This characteristic feature will be described in detail below.

FIG. 5 is a vertical sectional view illustrating a front-end region of the movable housing 200 when the cellular phone 10 according to the embodiment is in the closed state. FIG. 6 is a horizontal sectional view illustrating the front-end region of the movable housing 200 when the cellular phone 10 according to the embodiment is in the closed state.

Referring to FIGS. 5 and 6, the elastic sheet component 206 is a substantially flat-plate-like component composed of. for example, elastically deformable polyurethane-based resin and is attached to the lower surface at a front end of the movable housing 200 by bonding. By attaching the elastic sheet component 206 to the lower surface at the front end of the movable housing 200, the elastic sheet component 206 may be prevented from coming into contact with the upper surface of the stationary housing 100 when the cellular phone 10 is being changed from the closed state to the open state. In consequence, the present embodiment may reduce if not prevent damages to the control section provided on the upper surface of the stationary housing 100.

The protrusion 206a protrudes from substantially the middle of the lower surface of the elastic sheet component 206. The protrusion 206a is given a height that causes the protrusion 206a to be in contact with the stationary housing 100 when the cellular phone 10 is in the closed state.

The spring component 208 is bonded and fixed to substantially the middle of the upper surface of the elastic sheet component 206, that is, a region on the upper surface of the elastic sheet component 206 that corresponds to the protrusion 206a. The spring component 208 has a sheet-metal structure with an angular U-shape in cross section and integrally having a pair of leg segments 208a that are in contact with the lower surface at the front end of the movable housing 200 and a flexible flat segment 208b bridged between the two leg segments 208a.

With the above configuration, when the cellular phone 10 is in the closed state, the protrusion 206a of the elastic sheet component 206 attached to the movable housing 200 is in contact with the stationary housing 100 so that the entire elastic sheet component 206 is slightly elastically deformed. An elastic repulsive force of the elastic sheet component 206 causes the flat segment 208b of the spring component 208 to bend from the stationary housing 100 side towards the movable housing 200 side. Thus, a biasing force that biases the protrusion 206a of the elastic sheet component 206 towards the stationary housing 100 is generated in the flat segment 208b of the spring component 208. With the biasing force generated in the flat segment 208b, the spring component 208 causes the protrusion 206a of the elastic sheet component 206 to be elastically in contact with the stationary housing 100. In consequence, even when the stationary housing 100 and the movable housing 200 are biased away from each other and there is an excessive dimensional variation in the connecting mechanism 300 between the two housings 100 and 200, looseness between the two housings 100 and 200 in the thickness direction thereof may be absorbed in this embodiment.

Referring to FIG. 6, the protrusion 206a of the elastic sheet component 206 has a sloped surface that is inclined downward towards the rear of the movable housing 200, or in other words, a sloped surface that is inclined upward towards the front of the movable housing 200. By giving the protrusion 206a a sloped surface as in this embodiment, a pressing force elastically applied by the protrusion 206a of the elastic sheet component 206 to the stationary housing 100 may be gradually increased as the cellular phone 10 is changed from the open state to the closed state. Thus, the movable housing 200 may be smoothly slid relative to the stationary housing 100 when the cellular phone 10 is being changed from the open state to the closed state, thereby preventing a user of the cellular phone 10 from receiving a feeling of stickiness between the protrusion 206a and the stationary housing 100. In consequence, the present embodiment reduces looseness between the stationary housing 100 and the movable housing 200 in the thickness direction thereof without lowering the usability of the cellular phone 10 for the user.

As illustrated in FIGS. 5 and 6, the spring component 208 is fitted in a recess 200a with a specific depth formed in the surface of the movable housing 200 that faces the stationary housing 100. The spring component 208 allows the recess 200a to absorb the bending of the flat segment 208b occurring when biasing the protrusion 206a of the elastic sheet component 206 towards the stationary housing 100. This prevents plastic deformation of the spring component 208 when the flat segment 208b of the spring component 208 bends by an excessive amount.

As illustrated in FIG. 5, the movable housing 200 has a bisectional structure including a movable front casing 210 provided with the display screen 202 and a movable rear casing 220 located at the lower-surface side of the movable front casing 210. A mounting screw 230 for fixing the movable front casing 210 and the movable rear casing 220 to each other is attached to the front end of the movable housing 200. The elastic sheet component 206 according to this embodiment is attached to the lower surface at the front end of the movable housing 200 so as to cover the mounting screw 230. Thus, the elastic sheet component 206 may have both the function of reducing looseness between the stationary housing 100 and the movable housing 200 in the thickness direction thereof when the cellular phone 10 is in the closed state and the function of hiding the mounting screw 230. In consequence, the present embodiment reduces if not eliminates the need for preparing an additional cover for hiding the mounting screw 230, thereby allowing for a reduced number of components.

As described above, the cellular phone 10 according to this embodiment includes the elastic sheet component 206 attached to the surface of the movable housing 200 that faces the stationary housing 100 and having the protrusion 206a protruding towards the stationary housing 100, and also includes the spring component 208 that biases the protrusion 206a towards the stationary housing 100 so as to cause the biased protrusion 206a to be elastically in contact with the stationary housing 100 when the cellular phone 10 is in the closed state. Thus, in the cellular phone 10 according to this embodiment, looseness between the stationary housing 100 and the movable housing 200 in the thickness direction thereof when the cellular phone 10 is in the closed state may be effectively reduced.

In addition to the above-described embodiment, the present invention may be applied to various embodiments within the technical scope described in the claims.

Although the protrusion 206a protrudes from substantially the middle of the lower surface of the elastic sheet component 206 in the above embodiment, the protrusion 206a may alternatively be provided in another region in the lower surface of the elastic sheet component 206.

Although the spring component 208 is made up of a sheet-metal structure in the above embodiment, the spring component 208 may be made up of an alternative structure with elasticity of, for example, a metallic spring or a plastic spring.

Although the elastic sheet component 206 and the spring component 208 are provided in the movable housing 200 in the above embodiment, the elastic sheet component 206 and the spring component 208 may alternatively be provided in the stationary housing 100.

Although the information terminal device in the above embodiment is described as being applied to a cellular phone, the information terminal device is not limited to a cellular phone. For example, the information terminal device according to the present embodiment may be applied to other various kinds of information terminal devices, such as a compact information terminal device, like a personal digital assistant (PDA), a compact audio reproducing device, a portable television, and a portable game device.

All examples and conditional language recited herein are intended for pedagogical purposes to aid the reader in understanding the principles of the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present inventions has been described in detail, it should be understood that the various changes, substitutions, and alterations could be made hereto without departing from the spirit and scope of the invention.

What is claimed is:

1. An information terminal device that includes a first housing and a second housing slidably connected to each other with a connecting mechanism and that is changeable in state between a closed state in which the two housings overlap each other and an open state in which the two housings overlap each other by an area smaller than in the closed state, the information terminal device comprising:
an elastic sheet component attached to a surface of the second housing that faces the first housing and having a protrusion protruding towards the first housing; and
a biasing component that biases the protrusion towards the first housing so as to cause the biased protrusion to be elastically in contact with the first housing when the information terminal device is in the closed state.

2. The information terminal device according to claim 1, wherein the protrusion has a sloped surface that is inclined downward in a direction in which the second housing is slid relative to the first housing when the information terminal device is changed in state from the open state to the closed state.

3. The information terminal device according to claim 1, wherein the elastic sheet component is attached to the surface, facing the first housing, at an end of the second housing in a direction in which the second housing is slid relative to the first housing when the information terminal device is changed in state from the closed state to the open state.

4. The information terminal device according to claim 3, wherein a mounting screw for fixing a front casing and a rear casing making up the second housing to each other is attached to the end of the second housing, and wherein the elastic sheet component is attached to the surface, facing the first housing, at the end of the second housing so as to cover the mounting screw.

5. The information terminal device according to claim 1, wherein the biasing component is fitted in a recess with a specific depth formed in the surface of the second housing that faces the first housing and allows the recess to absorb bending of the biasing component occurring when biasing the protrusion towards the first housing.
